(19) United States
(12) Patent Application Publication
(10) Pub. No.: US 2015/0004798 A1
(43) Pub. Date: Jan. 1, 2015

(54) CHEMICAL DEPOSITION CHAMBER HAVING GAS SEAL

(71) Applicant: Lam Research Corporation, Fremont, CA (US)

(72) Inventors: Ramesh Chandrasekharan, Portland, OR (US); Saangrut Sangplung, Sherwood, OR (US)

(21) Appl. No.: 13/930,289

(22) Filed: Jun. 28, 2013

(51) Int. Cl. H01L 21/67

(52) U.S. Cl. CPC H01L 21/67017
USPC 438/758; 118/723 R

(57) ABSTRACT

A system for sealing a processing zone in a chemical deposition apparatus is disclosed, which includes a chemical isolation chamber having a deposition chamber formed within the chemical isolation chamber; a showerhead module having a faceplate, the showerhead module including a plurality of inlets which deliver reactor chemistries to a cavity for processing semiconductor substrates and exhaust outlets which remove reactor chemistries and inert gases from the cavity, and an outer plenum configured to deliver an inert gas; a pedestal module configured to support a substrate and which moves vertically to close the cavity with a narrow gap between the pedestal module and a step around an outer portion of the faceplate; and an inert seal gas feed configured to feed the inert seal gas into the outer plenum, and wherein the inert seal gas flows radially inwardly at least partly through the narrow gap to form a gas seal.

### FIELD OF THE INVENTION

This invention pertains to apparatuses and processes for conducting chemical depositions and for use in conducting plasma enhanced chemical depositions.

### BACKGROUND

Plasma processing apparatuses can be used to process semiconductor substrates by techniques including etching, physical vapor deposition (PVD), chemical vapor deposition (CVD), plasma enhanced chemical vapor deposition (PECVD), atomic layer deposition (ALD), plasma enhanced atomic layer deposition (PEALD), pulsed deposition layer (PDL), plasma enhanced pulsed deposition layer (PEPDL) processing, and resist removal. For example, one type of plasma processing apparatus used in plasma processing includes a reaction or deposition chamber containing top and bottom electrodes. A radio frequency (RF) power is applied between the electrodes to excite a process gas into a plasma for processing semiconductor substrates in the reaction chamber.

### SUMMARY

A system for sealing a processing zone in a chemical deposition apparatus is disclosed, comprising: a chemical isolation chamber having a deposition chamber formed within the chemical isolation chamber; a showerhead module having a faceplate and a backing plate, the showerhead module including a plurality of inlets which deliver reactor chemistries to a cavity for processing semiconductor substrates and exhaust outlets which remove reactor chemistries and inert gases from the cavity, and an outer plenum configured to deliver an inert gas; a pedestal module configured to support a substrate and which moves vertically to close the cavity with a narrow gap between the pedestal module and a step around an outer portion of the faceplate; and an inert seal gas feed configured to feed the inert seal gas into the outer plenum, and wherein the inert seal gas flows radially inwardly at least partly through the narrow gap to form a gas seal.

A method for preventing reactor chemistries from escaping from a cavity for processing semiconductor substrates is disclosed, comprising: processing a substrate in the cavity of a chemical deposition apparatus, the cavity formed between a showerhead module and a pedestal module configured to receive the substrate, wherein the showerhead module includes a plurality of inlets which delivers reactor chemistries to the cavity and exhaust outlets which remove reactor chemistries and inert gases from the cavity; and feeding an inert seal gas feed into an outer plenum configured to deliver the inert seal gas around an outer periphery of a faceplate of the showerhead module and into a narrow gap between the pedestal module and a step around an outer portion of the faceplate, which surrounds an outer edge of the cavity, and wherein the inert seal gas flows radially inwardly at least partly through the narrow gap to form a gas seal.

In accordance with an exemplary embodiment, the gas based sealing system is configured to prevent the escape of reactor chemistries during different ALD process steps. For example, ALD process steps can differ by multiple factors or even orders of magnitude in terms of reactor pressures and flow rates. Accordingly, it would be desirable to achieve a gas seal of the wafer or reactor cavity during ALD process steps using a seal gas as the mechanism to contain reactor chemistries and isolate the reactor or cavity.

### BRIEF DESCRIPTION OF THE DRAWING FIGURES

FIG. 1A is a schematic diagram showing a chemical deposition apparatus with a pedestal in accordance with an exemplary embodiment.

FIG. 1B is a schematic diagram showing a chemical deposition apparatus without a pedestal in accordance with an exemplary embodiment.

FIG. 2 is a cross-sectional view of a gas based sealing system in accordance with an exemplary embodiment.

FIG. 3 is a cross-sectional view of a gas based sealing system in accordance with an exemplary embodiment.

FIG. 4 is a cross-sectional view of a gas based sealing system in accordance with an exemplary embodiment.

FIG. 5 is a cross-sectional view of a gas based sealing system in accordance with an exemplary embodiment.

FIG. 6 is a cross-sectional view of a gas based sealing system in accordance with an exemplary embodiment.

FIG. 7 is a schematic of a gas based sealing system in accordance with an exemplary embodiment.

FIG. 8 is a chart showing pressure and valve angle versus time for a gas based sealing system in accordance with an exemplary embodiment.

### DETAILED DESCRIPTION

In the following detailed disclosure, exemplary embodiments are set forth in order to provide an understanding of the apparatus and methods disclosed herein. However, as will be apparent to those skilled in the art, that the exemplary embodiments may be practiced without these specific details or by using alternate elements or processes. In other instances, well-known processes, procedures, and/or components have not been described in detail so as not to unnecessarily obscure aspects of embodiments disclosed herein.

In accordance with an exemplary embodiment, the apparatuses and associated methods disclosed herein can be used for a chemical deposition such as a plasma enhanced chemical deposition. The apparatus and methods can be used in conjunction with a semiconductor fabrication based dielectric deposition process that requires separation of self-limiting deposition steps in a multi-step deposition process (for example, atomic layer deposition (ALD), plasma enhanced atomic layer deposition (PEALD), pulsed deposition layer (PDL), or plasma enhanced pulsed deposition layer (PEPDL) processing), however they are not so limited.

As indicated, present embodiments provide apparatus and associated methods for conducting a chemical deposition such as a plasma enhanced chemical vapor deposition. The apparatus and methods are particularly applicable for use in conjunction with semiconductor fabrication based dielectric deposition processes which require separation of self-limiting deposition steps in a multi-step deposition process (e.g., atomic layer deposition (ALD), plasma enhanced atomic layer deposition (PEALD), plasma enhanced chemical vapor deposition (PECVD), pulsed deposition layer (PDL), or plasma enhanced pulsed deposition layer (PEPDL) processing), however they are not so limited.

The aforementioned processes can suffer from some drawbacks associated with nonuniform temperatures across a wafer or substrate receiving deposited material. For example, nonuniform temperatures may develop across a substrate when a passively heated showerhead, which is in thermal contact with surrounding chamber components, loses heat to the surrounding components. Therefore, the showerhead which forms an upper wall of a processing zone is preferably thermally isolated from the surrounding components such that an isothermal processing zone may be formed, thereby forming uniform temperatures across the substrate. The uniform temperatures across the substrate aid in the uniform processing of substrates wherein the substrate temperature provides activation energy for the deposition process and is therefore a control means for driving the deposition reaction.

Further, there are generally two main types of deposition showerheads, the chandelier type and the flush mount. The chandelier showerheads have a stem attached to the top of the chamber on one end and the faceplate on the other end, resembling a chandelier. A part of the stem may protrude the chamber top to enable connection of gas lines and RF power. The flush mount showerheads are integrated into the top of a chamber and do not have a stem. Present embodiments pertain to a flush mount type showerhead wherein the flush mount showerhead reduces chamber volume, which must be evacuated by a vacuum source during processing.

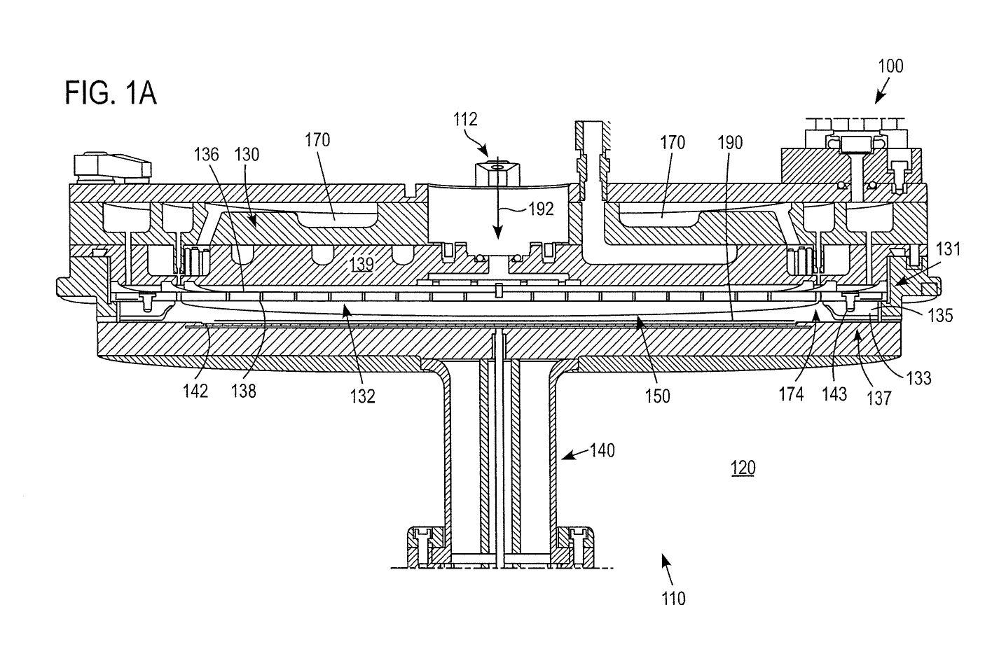

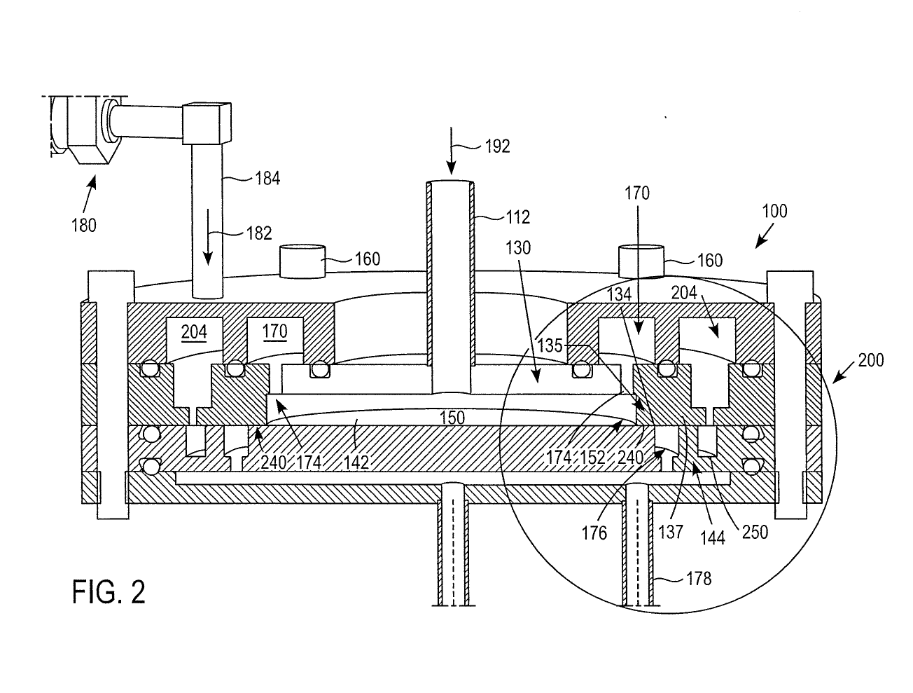

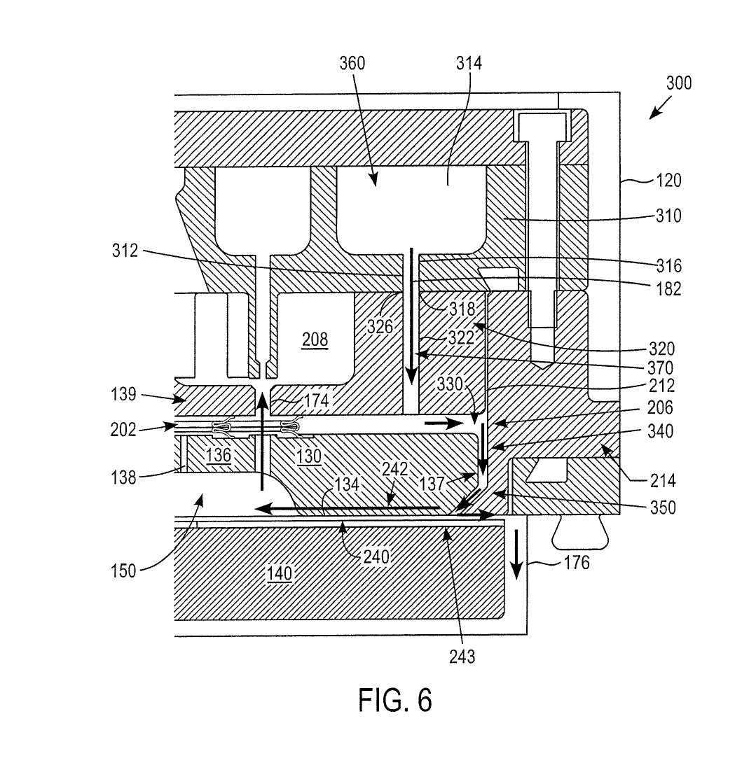

FIGS. 1A and 1B are schematic diagrams showing a chemical deposition apparatus 100 in accordance with embodiments disclosed herein. As shown in FIGS. 1A and 1B, the chemical apparatus includes a chemical isolation chamber or housing 110, a deposition chamber 120, a showerhead module 130, and a moving pedestal module 140 that can be vertically raised or lowered relative to the showerhead module 130 to raise and lower a substrate (or wafer) 190 position on an upper surface of the pedestal module 140. The showerhead module 130 can also be vertically raised and lowered. Reactant material gases (or process gases) 192 (FIG. 3) are introduced into the sub-chamber (or cavity) 150 via gas lines 112 through a central plenum 202 (FIG. 6) of the showerhead module 130. Each of the gas lines 112 may have a corresponding accumulator (not shown), which can be isolated from the apparatus 100 using isolation valves 116. In accordance with an exemplary embodiment, the apparatus 100 can be modified to have one or more gas lines 112 with isolation valves and accumulators, depending on the number of reactant gases used. Also, reactant gas delivery lines 112 can be shared between a plurality of chemical deposition apparatuses or multi-station system.

In accordance with an exemplary embodiment, the chamber 120 can be evacuated through one or more vacuum lines 160 that are connected to a vacuum source (not shown). For example, the vacuum source can be a vacuum pump (not shown). In multi-station reactors, for example, those having multiple stations or apparatuses 100 that perform the same deposition process, a vacuum line 160 from another station may share a common foreline with the vacuum line 160. In addition, the apparatus 100 can be modified to have one or more vacuum lines 160 per station or apparatus 100.

In accordance with an exemplary embodiment, a plurality of evacuation conduits 170 can be configured to be in fluid communication with one or more exhaust outlets 174 within the faceplate 136 of the showerhead module 130. The exhaust outlets 174 can be configured to remove process gases or reactor chemistries 192 from the cavity 150 between deposition processes. The plurality of evacuation conduits 170 are also in fluid communication with the one or more vacuum lines 160. The evacuation conduits 170 can be spaced circumferentially around the substrate 190 and may be evenly spaced. In some instances, the spacing of plurality of conduits 170 may be designed to compensate for the locations of the vacuum lines 160. Because there are generally fewer vacuum lines 160 than there are plurality of conduits 170, the flow through the conduit 170 nearest to a vacuum line 160 may be higher than one further away. To ensure a smooth flow pattern, the conduits 170 may be spaced closer together if they are further away from the vacuum lines 160. An exemplary embodiment of a chemical deposition apparatus 100 including a plurality of conduits 170 including a variable flow conductor can be found in commonly assigned U.S. Pat. No. 7,993,457, which is hereby incorporated by reference in its entirety.

Embodiments disclosed herein are preferably implemented in a plasma enhanced chemical deposition apparatus (e.g., PECVD apparatus, PEALD apparatus, or PEPDL apparatus). Such an apparatus may take different forms wherein the apparatus can include one or more chambers or “reactors” 110, which can include multiple stations or deposition chambers 120 as described above, that house one or more substrates 190 and are suitable for substrate processing. Each chamber 120 may house one or more substrates for processing. The one or more chambers 120 maintain the substrate 190 in a defined position or positions (with or without motion within that position, e.g. rotation, vibration, or other agitation). In one embodiment, a substrate 190 undergoing deposition and treatment can be transferred from one station (e.g. deposition chamber 120) to another within the apparatus 100 during the process. While in process, each substrate 190 is held in place by a pedestal, wafer chuck and/or other wafer holding apparatus 140. For certain operations in which the substrate 190 is to be heated, the apparatus 140 may include a heater such as a heating plate.

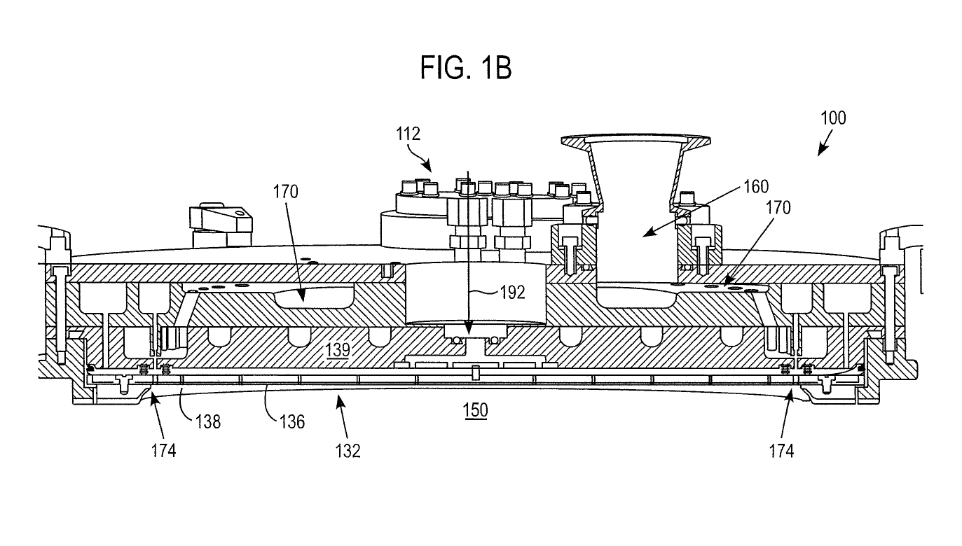

FIG. 2 is a cross-sectional view of a chemical deposition apparatus 100 having a gas based sealing system 200 in accordance with an exemplary embodiment. As shown in FIG. 2, the chemical deposition apparatus 100 includes a substrate pedestal module 140, which is configured to receive and/or discharge a semiconductor substrate (or wafer) 190 from an upper surface 142 of the pedestal module 140. In a lower position, a substrate 190 is placed on the surface of the pedestal module 140, which is then raised vertically upward towards the showerhead module 130. In accordance with an exemplary embodiment, the distance between the upper surface 142 of the pedestal module 140 and a lower surface 132 of the showerhead module 130, which forms a cavity 150 can be about 0.2 inches (5 millimeters) to about 0.6 inches (15 millimeters). The upward vertical movement of the pedestal module 140 to close the cavity 150 creates a narrow gap 240 between the pedestal and a step 135 around an outer portion 131 of the faceplate 136 (FIGS. 1A and 1B) of the showerhead module 130.

In an exemplary embodiment, the temperature inside the chamber 120 can be maintained through a heating mechanism in the showerhead module 130 and/or the pedestal module 140. For example, the substrate 190 can be located in an isothermal environment wherein the showerhead module 130 and the pedestal module 140 are configured to maintain the substrate 190 at a desired temperature. In an exemplary embodiment, the showerhead module 130 can be heated to greater than 250° C., and/or the pedestal module 140 can be heated in the 50° C. to 550° C. range. The deposition chamber or cavity 150 serves to contain the plasma generated by a capacitively coupled plasma type system including the showerhead module 130 working in conjunction with the pedestal module 140.

RF source(s) (not shown), such as a high-frequency (HF) RF generator, connected to a matching network (not shown), and a low-frequency (LF) RF generator are connected to showerhead module 130. The power and frequency supplied by matching network is sufficient to generate a plasma from the process gas/vapor. In an embodiment, both the HF generator and the LF generator can be used. In a typical process, the HF generator is operated generally at frequencies of about 2-100 MHz; in a preferred embodiment at 13.56 MHz. The LF generator is operated generally at about 50 kHz to 2 MHz; in a preferred embodiment at about 350 to 600 kHz. The process parameters may be scaled based on the chamber volume, substrate size, and other factors. For example, power outputs of LF and HF generators are typically directly proportional to the deposition surface area of the substrate. The power used on 300 mm wafers will generally be at least 2.25 higher than the power used for 200 mm wafers. Similarly, the flow rates, such as standard vapor pressure, for example, can depend on the free volume of the deposition chamber 120.

Within the deposition chamber 120, the pedestal module 140 supports the substrate 190 on which materials may be deposited. The pedestal module 140 typically includes a chuck, a fork, or lift pins to hold and transfer the substrate during and between the deposition and/or plasma treatment reactions. The pedestal module 140 may include an electrostatic chuck, a mechanical chuck, or various other types of chuck as are available for use in the industry and/or research. The pedestal module 140 can be coupled with a heater block for heating the substrate 190 to a desired temperature. Generally, the substrate 190 is maintained at a temperature of about 25° C. to 500° C. depending on the material to be deposited.

In accordance with an exemplary embodiment, the gas based sealing system 200 can be configured to help control and regulate flow out from the cavity 150 during flow of process material or purge gas. In accordance with an exemplary embodiment, the evacuation or purging of the chamber 150 uses an inert or purge gas (not shown), which is fed into the cavity 150 through the showerhead module 130. In accordance with an exemplary embodiment, one or more conduits 178 can be connected to the vacuum lines 160 via an annular evacuation passage 176, which is configured to remove seal gas 182 (FIG. 2) from a zone below the pedestal module 140.

In accordance with an exemplary embodiment, the showerhead module 130 is configured to deliver reactor chemistries to the cavity (or reactor chamber) 150. The showerhead module 130 can include a faceplate 136 having a plurality of inlets or through holes 138 and a backing plate 139. In accordance with an exemplary embodiment, the faceplate 136 can be a single plate having a plurality of inlets or through holes 138 and the step 135, which extends around the outer periphery 137 of the faceplate 136. Alternatively, the step 135 can be a separate ring 133, which is secured to a lower surface of an outer portion 131 of the faceplate 136. For example, the step 135 can be secured to the outer portion 131 of the faceplate 136 with a screw 143. An exemplary embodiment of a showerhead module 130 for distribution of process gases including a faceplate 136 having concentric exhaust outlets 174 can be found in commonly assigned U.S. Pat. No. 5,614,026, which is hereby incorporated by reference in its entirety. For example, in accordance with an exemplary embodiment, the exhaust outlets 174 surround the plurality of inlets 138.

In accordance with an exemplary embodiment, the cavity 150 is formed beneath a lower surface 132 of the faceplate 136 of the showerhead module 130 and an upper surface 142 of the substrate pedestal module 140. A plurality of concentric evacuation conduits or exhaust outlets 174 within the faceplate 136 of the showerhead module 130 can be fluidly connected to the one or more of the plurality of conduits 170 to remove process gases or reactor chemistries 192 from the cavity 150 between deposition processes.

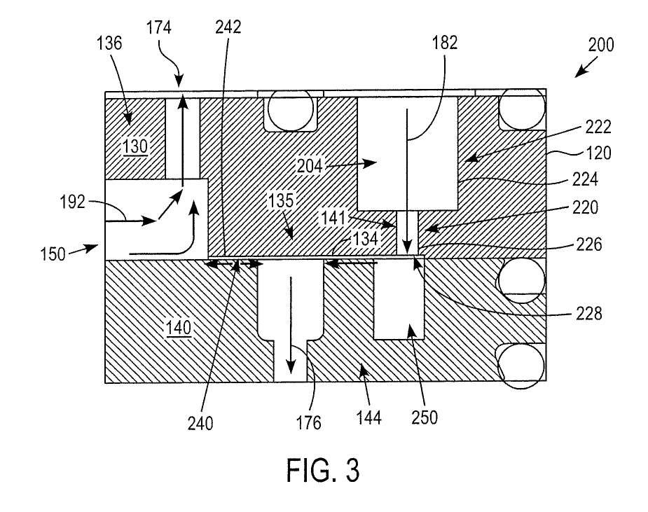

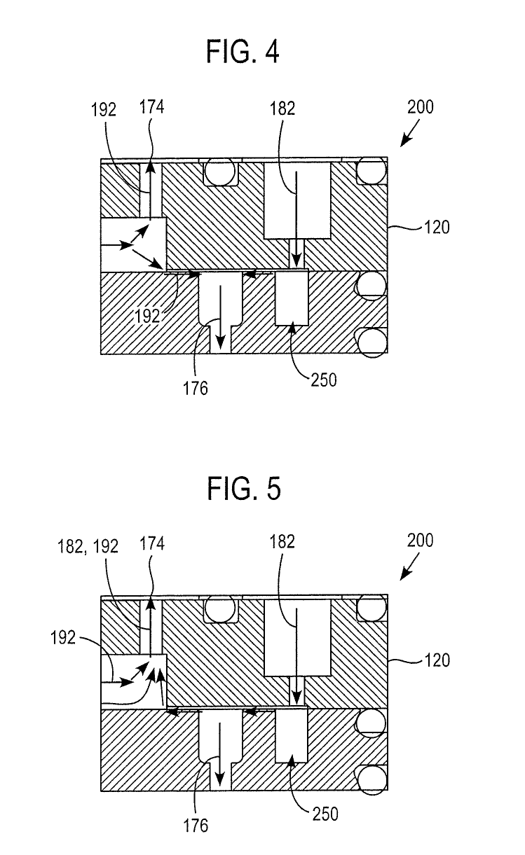

As shown in FIG. 2, the apparatus 100 also includes a source 180 of inert gas or seal gas 182, which is fed through the one or more conduits 184 to an outer plenum 204 of the gas based sealing system 200. In accordance with an exemplary embodiment, the inert or seal gas 182 can be a nitrogen gas or argon gas. In accordance with an exemplary embodiment, the inert gas source 180 is configured to feed an inert seal gas 182 via one or more conduits 184 radially inward through a narrow gap 240, which extends outward from the cavity 150 and is formed between a lower surface 134 of a step 135 around an outer periphery 137 of the faceplate 136 and the upper surface 142 of the pedestal module 140. In accordance with an exemplary embodiment, the inert seal gas 182 communicates with process gases or reactor chemistries 192 (FIG. 3) from the cavity 150 within the narrow gap 240 to form a gas seal during processing. As shown in FIGS. 3 and 4, the inert seal gas 182 only partly enters the narrow gap 240, which forms a gas seal between the reactor chemistries 192 and the inert gas 182 within the narrow gap. Alternatively, as shown in FIGS. 5 and 6, the flow of the inert gas 182 can be to an outer edge of the cavity 150 and removed from the cavity 150 through the one or more exhaust outlets 174 within the showerhead module 130.

In accordance with an exemplary embodiment, an annular evacuation passage 176 is fluidly connected to one or more of the plurality of evacuation conduits 170. In accordance with an exemplary embodiment, the annular evacuation passage 176 has one or more outlets (not shown) and is configured to remove the inert gases 182 from the zone surrounding the periphery of the substrate 190 and the inert gases 182 traveling or flowing radially inward through the narrow gap 240. The evacuation passage 176 is formed within an outer portion 144 of the substrate pedestal 140. The annular evacuation passage 176 can also be configured to remove the inert gases 182 from underneath the substrate pedestal 140. Further embodiments with multiple conduits similar to 176 can aid in drawing more inert gas 182 and enabling higher flow of inert gas into 178 and portion below pedestal. The multiple conduits 176 can also aid in a higher pressure drop on the sealing surface and hence lower diffusion into the wafer cavity.

FIG. 3 is a cross-sectional view of a portion of a deposition chamber 120 of a chemical deposition apparatus 100 having a gas based sealing system 200 in accordance with an exemplary embodiment. As shown in FIG. 3, the outer plenum 204 can be formed in an outer portion 131 of the faceplate 136. The outer plenum 204 can include one or more conduits 220, which are configured to receive the inert gas 182 from the inert gas source or feed 180. The inert gas 182 flows through the outer plenum 204 via the one or more conduits 220 to a lower outlet 228. The lower outlet 228 is in fluid communication with the narrow gap 240. In accordance with an exemplary embodiment, a distance from the outer edge 152 of the cavity 150 to an outer periphery or edge 141 of the faceplate 136 in communication with the outer plenum 204 is at a finitely controlled distance. For example, the distance (or width) from the outer edge 152 of the cavity 150 to the outer edge 141 of the faceplate 136 in communication with the outer plenum 204 can be from about 5.0 mm to 25.0 mm.

In accordance with an exemplary embodiment, the one or more conduits 220 which form the outer plenum 204 are an outer annular recess 222. The outer annular recess 222 is configured to be in fluid communication with the narrow gap 240 on an outer edge of the cavity 150. The outer annular recess 222 can be configured to have an upper annular recess 224 and a lower annular recess 226, wherein the upper annular recess 224 has a greater width than the lower annular recess 226. In accordance with an exemplary embodiment, the lower outlet 228 is annular outlet on a lower portion of the lower annular recess 226, which is in fluid communication with the narrow gap 240.

In accordance with an exemplary embodiment, as shown in FIG. 3, the inert gas 182 is fed through the outer plenum 204 at the edge of the reactor or cavity 150 spaced at finitely controlled distances. The flow rate of the inert gas 182 flowing through the outer plenum 204 can be such that the Peclet number is greater than about 1.0, thus containing the chemistries 192 within the cavity 150 as shown in FIG. 3. For example, if the Peclet number is greater than 1.0, the inert gas 182 and the reactor chemistries 192 can establish an equilibrium within an inner portion 242 of the narrow gap 240, which prevents the reactor chemistries 192 from flowing beneath the substrate pedestal 140 and contaminating portions of the deposition chamber 120 outside of the cavity 150.

In accordance with an exemplary embodiment, if the process is a constant pressure process, then a single (or constant) flow of the inert gas 182 in combination with the pressure from below the pedestal 140 can be sufficient to ensure a seal between the reactor chemistries 192 within the cavity 150 and the inert gas 180 flowing radially inward through the narrow gap 240. For example, in accordance with an exemplary embodiment, the gas based sealing system 200, can be used with ALD oxides of Si, which can be generally run in a relatively constant pressure mode. In addition, the gas based sealing system 200 can act as a means to control sealing across different processes and pressure regimes within the deposition chamber 120 and the cavity 150, for example, during an ALD nitride process by varying the flow rate of the inert gas 182 or pressure below the pedestal module 140 and/or a combination of both.

In accordance with an exemplary embodiment, the sealing gas system 200 as disclosed individually, or in combination with the pressures associated with the exhaust conduits 174, 176 can help prevent flow and/or diffusion of reactor chemistries 192 out of 150 during processing. In addition, the system 200 individually, or in combination with the exhaust conduits 174, 176 and pressure associated with the exhaust conduits 174, 176 can also prevent the bulk flow of the inert gas 182 into the cavity 150 and over onto the substrate 190. In addition, the flow rate of the inert gas 182 into the narrow gap 240 to isolate the cavity 150 can be adjusted based on the pressure produced by the exhaust outlets 174. In accordance with an exemplary embodiment, for example, the inert gas or seal gas 182 can be fed through the outer plenum 204 at a rate of about 100 cc/minute to about 5.0 standard liters per minute (slm), which can be used to isolate the cavity 150.

In accordance with an exemplary embodiment, one or more cavities 250 can be located in an outer portion of the pedestal module 140, which surrounds the cavity 150. The one or more cavities 250 can be in fluid communication with the narrow gap 240 and the lower outlet 228, which can add to the pressure drop from the cavity 150 to the inert or gas feed 180. The one or more cavities 250 (or annular channel) can also provide an added control mechanism to enable sealing across various process and pressure regimes, for example, during ALD nitride processing. In accordance with an exemplary embodiment, the one or more cavities 250 can be equally spaced around the deposition chamber 120. In an exemplary embodiment, the one or more cavities 250 are an annular channel, which is concentric and of larger width than the lower outlet 228.

FIG. 4 is a cross-sectional view of a portion of the deposition chamber 120 of a chemical deposition apparatus 100 with a gas based sealing system 200. As shown in FIG. 4, if the flow rate of the reactor chemistries 192 is greater than or about equal to the flow rate of the inert gas 182, the flow of the reactor chemistries 192 may extend outside of the cavity 150, which may not be desirable.

As shown in FIG. 4, the annular evacuation passage 176 is fluidly connected to one or more of the plurality of evacuation conduits 170. The annular evacuation passage 176 is configured to remove the inert gases 182 from underneath the substrate pedestal 140 and from a zone surrounding a periphery of the substrate 190. In accordance with an exemplary embodiment, the evacuation passage 176 has one or more outlets (not shown) and is configured to remove the inert gases 182 from the zone surrounding the periphery of the substrate 190 and the inert gases 182 flowing or diffusing radially inward through the narrow gap 240.

FIG. 5 is a cross-sectional view of a portion of the deposition chamber 120 of a chemical deposition apparatus 100 with a gas based sealing system 200 in accordance with an exemplary embodiment. The flow of inert gas 182 from outside the cavity 150 can be produced by reducing the flow rate of the reactor chemistries 192 and/or increasing the flow rate of the inert gas 182. In accordance with an exemplary embodiment, the inert gas 182 from the outer plenum 204 will flow into the cavity 150 and can be removed through the one or more exhaust outlets 174 within the showerhead module 130.

FIG. 6 is a cross-sectional view of a portion of the deposition chamber 120 of a chemical deposition apparatus 100 with a gas based sealing system 300 in accordance with an exemplary embodiment. In accordance with an exemplary embodiment, a central plenum 202 of the showerhead module 130 includes the plurality of inlets or through-holes 138, which delivers the reactor chemistries 192 to the cavity 150. The cavity 150 also includes concentric conduits or exhaust outlets 174 which remove reactor chemistries 192 and inert gases 182 from the cavity 150. The concentric conduits or exhaust outlets 174 can be in fluid communication with an intermediate plenum 208. The intermediate plenum 208 being fluidly connected to one or more of the plurality of evacuation conduits 170.

The showerhead module 130 can also include vertical gas passage 370, which is configured to deliver an inert gas 182 around an outer periphery 137 of the faceplate 136. In accordance with an exemplary embodiment, an outer plenum 206 can be formed between an outer periphery 137 of the faceplate 136 and an inner periphery or edge 212 of an isolation ring 214.

As shown in FIG. 6, the system 300 includes a vertical gas passage 370 formed within an inner channel 360 within an upper plate 310 and an outer portion 320 of the backing plate 139. The vertical gas passage 370 includes one or more conduits 312, 322, which are configured to receive the inert gas 182 from the inert gas source or feed 180. In accordance with an exemplary embodiment, the inert gas 182 flows through the upper plate 310 and the outer portion 320 of the backing plate 139 via the one or more conduits 312, 322 to one or more recesses and/or channels 330, 340, 350 to an outer edge of the reactor or cavity 150.

In accordance with an exemplary embodiment, the one or more conduits 312 can include an upper annular recess 314 and a lower outer annular recess 316. In accordance with an exemplary embodiment, the upper recess 314 has a greater width than the lower recess 316. In addition, the one or more conduits 322 can be within the upper plate 310 and the outer portion 320 of the backing plate 139. The one or more conduits 322 can form an annular recess having an inlet 326 in fluid communication with an outlet 318 on the upper plate 310 and an outlet 328 in fluid communication with the narrow gap 240. In accordance with an exemplary embodiment, the outlet 328 within the lower isolation ring 320 can be in fluid communication with one or more recesses and/or channels 330, 340, 350, which guides the flow of the inert gas 182 around an outer periphery of the faceplate 136 of the showerhead module 130 to an outer edge 243 of the narrow gap 240.

In accordance with an exemplary embodiment, the inert gas 182 is fed through the vertical gas passage 370 to the outer plenum 206, and radially inwardly at least partly through the narrow gap 240 towards the cavity 150. The flow rate of the inert gas 182 flowing through the one or recesses and/or channels 330, 340, 350 can be such that the Peclet number is greater than 1.0, thus containing the chemistries 192 within the cavity 150. In accordance with an exemplary embodiment, if the Peclet number is greater than 1.0, the inert gas 182 and the reactor chemistries 192 establishes an equilibrium within the inner portion 242 of the narrow gap 240, which prevents the reactor chemistries 192 from flowing beneath the pedestal module 140 and contaminating portions of the deposition chamber 120 outside of the cavity 150. In accordance with an exemplary embodiment, by containing the flow of the reactor chemistries 192 to the cavity 150, the system 200 can reduce the usage of reactor chemistries 192. In addition, the system 200 can also reduce the fill time of the cavity 150 with the reactor chemistries 192 during processing.

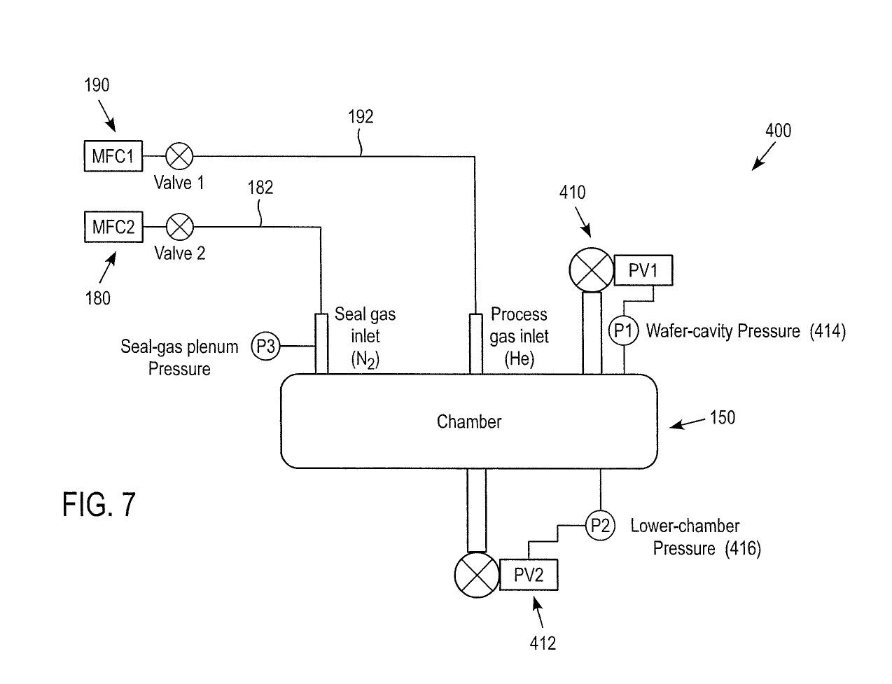

FIG. 7 is a schematic of a gas based sealing system 400 in accordance with an exemplary embodiment. As shown in FIG. 7, the system 400 includes a source of an inert or seal gas 180 and source of a process gas 190, which are configured to deliver an inert or seal gas 182 and a process gas 192, respectively, to the cavity 150. The system 400 can also include a wafer-cavity or cavity pressure valve 410 and a lower chamber pressure valve 412, which control a wafer-cavity or cavity pressure 414, and a lower chamber pressure 416, respectively.

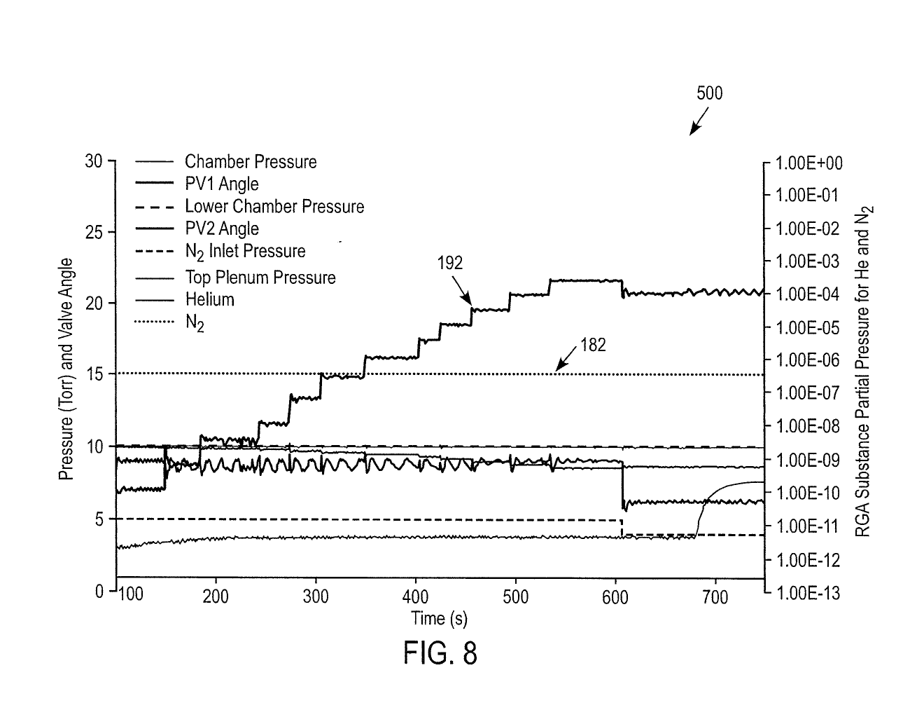

FIG. 8 is a chart 500 showing pressure and valve angle versus time for a gas based sealing system 400 in accordance with an exemplary embodiment. In accordance with an exemplary embodiment, as shown in FIG. 8, a process gas 192 in the form of helium was delivered to the cavity 150 at flow rates of 0 to about 20 SLM (standard liters per minute). An inert or seal gas 182 in the form of nitrogen gas (N₂) was provided to the cavity at about 2 SLM. In accordance with an exemplary embodiment, the cavity chamber 414 and the lower chamber pressure 416 was approximately 10 Torr. As shown in FIG. 8, at operating conditions of up to about 20 SLM of helium gas 192 and 2 SLM of nitrogen gas 182, the helium gas 182 did not leak through the purge channel as evidenced by the Residual Gas Analyzer measurements (or narrow gap 240).

Also disclosed herein is a method of processing a semiconductor substrate in a processing apparatus. The method comprises supplying process gas from the process gas source into the deposition chamber, and processing a semiconductor substrate in the plasma processing chamber. The method preferably comprises plasma processing the substrate wherein RF energy is applied to the process gas using an RF generator, which generates the plasma in the deposition chamber.

When the word “about” is used in this specification in connection with a numerical value, it is intended that the associated numerical value include a tolerance of ±10% around the stated numerical value.

Moreover, when the words “generally”, “relatively”, and “substantially” are used in connection with geometric shapes, it is intended that precision of the geometric shape is not required but that latitude for the shape is within the scope of the disclosure. When used with geometric terms, the words “generally”, “relatively”, and “substantially” are intended to encompass not only features, which meet the strict definitions, but also features, which fairly approximate the strict definitions.

While the plasma processing apparatus including an isothermal deposition chamber has been described in detail with reference to specific embodiments thereof, it will be apparent to those skilled in the art that various changes and modifications can be made, and equivalents employed, without departing from the scope of the appended claims.

What is claimed is:

1. A system for sealing a processing zone in a chemical deposition apparatus, comprising:
a chemical isolation chamber having a deposition chamber formed within the chemical isolation chamber;
a showerhead module having a faceplate and a backing plate, the showerhead module including a plurality of inlets which deliver reactor chemistries to a cavity for processing semiconductor substrates and exhaust outlets which remove reactor chemistries and inert gases from the cavity, and an outer plenum configured to deliver an inert gas;
a pedestal module configured to support a substrate and which moves vertically to close the cavity with a narrow gap between the pedestal module and a step around an outer portion of the faceplate; and
an inert seal gas feed configured to feed the inert seal gas into the outer plenum, and wherein the inert seal gas flows radially inwardly at least partly through the narrow gap to form a gas seal.

2. The system of claim 1, comprising:
an annular evacuation passage which removes the inert sealing gases flowing radially inwardly through the narrow gap and from a zone surrounding a periphery of a substrate on an upper surface of the pedestal module.

3. The system of claim 2, wherein the annular evacuation passage is located underneath the step of the faceplate.

4. The system of claim 1, comprising:
a semiconductor substrate on an upper surface of the pedestal module.

5. The system of claim 1, wherein the outer plenum is formed between an outer periphery of the faceplate and an inner periphery of an isolation ring.

6. The system of claim 5, wherein the outer plenum is an annular conduit.

7. The system of claim 1, wherein the narrow gap has a width of about 5.0 mm to 25.0 mm from an outer edge of the cavity to an outer edge of the faceplate.

8. The system of claim 1, wherein the exhaust outlets surround the plurality of inlets.

9. The system of claim 1, wherein the inert seal gas is a nitrogen gas or an argon gas.

10. The system of claim 2, comprising:
at least one evacuation conduit in fluid communication with the annular evacuation passage; and
an evacuation apparatus in fluid communication with the at least one evacuation conduit.

11. The system of claim 1, comprising:
at least one evacuation conduit in fluid communication with an intermediate plenum; and
an evacuation apparatus in fluid communication with the plurality of evacuation conduits.

12. The system of claim 1, comprising:
one or more cavities located in the pedestal module, and wherein the one or more cavities are configured to be fluid communication with the outer plenum.

13. The system of claim 12, wherein the one or more cavities in the pedestal module is an annular channel.

14. The system of claim 1, wherein the step around the outer portion of the faceplate is a separate ring.

15. A method for preventing reactor chemistries from escaping from a cavity for processing semiconductor substrates, comprising:
processing a substrate in the cavity of a chemical deposition apparatus, the cavity formed between a showerhead module and a pedestal module configured to receive the substrate, wherein the showerhead module includes a plurality of inlets which delivers reactor chemistries to the cavity and exhaust outlets which remove reactor chemistries and inert gases from the cavity;
feeding an inert seal gas feed into an outer plenum configured to deliver the inert gas into a narrow gap between the pedestal module and a step around an outer portion of the faceplate, which surrounds an outer edge of the cavity; and
flowing the inert seal gas radially inwardly at least partly through the narrow gap to form a gas seal.

16. The method of claim 15, comprising:
purging the cavity of reactor chemistries by increasing the flow rate of the inert seal gas into the cavity through the narrow gap; and
evacuating the reactor chemistries from the cavity with an evacuation apparatus fluidly connected to the concentric outlets of the showerhead module.

17. The method of claim 16, comprising
removing the inert seal gas from a zone surrounding a periphery of the substrate on the pedestal module through an evacuation passage in fluid communication with an evacuation apparatus.

18. The method of claim 15, comprising:
flowing the inert seal gas into the narrow gap at a Peclet number greater than about 1.0.

19. The method of claim 15, comprising:
depositing a layer on a substrate via at least one of the following processes:
chemical vapor deposition, plasma-enhanced chemical vapor deposition, atomic layer deposition, plasma-enhanced atomic layer deposition, pulsed layer deposition, and/or plasma enhanced pulsed deposition.

20. The method of claim 15, comprising:
feeding the inert seal gas to the narrow gap at about 100 cc/minute to about 5.0 slm (standard liters per minute).

21. The method of claim 15, comprising:
adjusting the flow rate of the inert seal gas into the narrow gap based on a pressure produced by the exhaust outlets surrounding the plurality of inlets.

22. The method of claim 15, comprising adjusting a pressure in an inner portion of an isolation chamber of the chemical deposition apparatus and which is located outside the cavity, and wherein the pressure adjustment is in tandem with changes in cavity pressure and process gas flow rate to enable sealing with minimized diffusion of the inert seal gas into the cavity.

23. The method of claim 15, comprising:
adjusting the flow rate of the inert seal gas to enable sealing and low diffusion of the inert gas into the cavity.
